(19) United States
(12) Patent Application Publication
(10) Pub. No.: US 2011/0164363 A1
(43) Pub. Date: Jul. 7, 2011

(54) PORTABLE ELECTRONIC DEVICE

(75) Inventor: Kazunori Kono, Kanagawa (JP)

(73) Assignee: PANASONIC CORPORATION, Osaka (JP)

(21) Appl. No.: 13/063,734

(22) PCT Filed: May 28, 2009
(86) PCT No.: PCT/JP2009/002374

§ 371 Date: Mar. 11, 2011

(30) Foreign Application Priority Data
Sep. 12, 2008 (JP) 2008-234784

(51) Int. Cl. H05K 7/00

(52) U.S. Cl. 361/679.01

(57) ABSTRACT

To provide a portable electronic device which can obtain good operability in the laterally opened state of the portable electronic device which can place a first housing and a second housing thereof in a longitudinally opened and the laterally opened state. In a portable terminal 10, since a first coupling shaft 41 for coupling a first housing 20 with a coupling portion 40 is disposed between an operation surface 20a of the first housing 20 and an outer surface 20b on the opposite side of the operation surface 20a, the coupling portion 40 does not protrude with respect to the operation surface 20a of the first housing 20. Thus, there is little possibility that the fingers of a user interferes with the coupling portion 40 in the laterally opened state. Thus, the operability of a user in the laterally opened state can be improved as compared with the background art. Further, in the portable terminal 10, since the effective area of an operation portion 21 with respect to the flat area of the first housing 20 can be secured to be large, it becomes possible to enlarge the sizes of operation buttons 21a, 21b and the arrangement interval thereof and hence the degree of freedom of the design is improved.

### TECHNICAL FIELD

The present invention relates to a foldable portable electronic device.

### BACKGROUND ART

There is known a foldable portable electronic device which can open and close, via a hinge mechanism, a first housing mainly having an operation portion and a second housing mainly having a liquid crystal screen (see Patent Literature 1, for example).

In recent years, users transmit/receive e-mails, play games and receive television broadcasting by using the liquid crystal screen and the operation portion of such the portable electronic device. In accordance with such the diversification of the using modes of the portable electronic device, at the time of transmitting/receiving an e-mail or playing a game, for example, it is convenient to place the device in a so-called longitudinally opened state where a lower housing (first housing) and an upper housing (second housing) are opened in the longitudinal direction via a coupling portion (hinge mechanism) to thereby dispose the liquid crystal screen and the operation portion in the longitudinal direction so that a user can operate by using a single hand while viewing the liquid crystal screen. On the other hand, at the time of playing a game or receiving television broadcasting, it is convenient to place the device in a so-called laterally opened state where the first housing and the second housing are opened in the width direction (lateral direction) so that the liquid crystal screen is used in a laterally laid manner.

Thus, a portable terminal as the portable electronic device described in Patent Literature 1 can be placed in the longitudinally opened state and the laterally opened state where the first housing and the second housing are opened in the longitudinal direction and the lateral direction via the hinge mechanism, respectively,

### Citation List

### Patent Literature

Patent Literature 1; JP-2006-22899A

### SUMMARY OF THE INVENTION

### Technical Problem

However, according to the portable terminal described in Patent Literature 1, since a first coupling shaft for coupling the lower housing and the coupling portion is fixed at a portion protruded from the surface of the lower housing, the coupling portion protrudes from the surface (operation surface) of the lower housing in the laterally opened state where the upper housing is rotated with respect to the lower housing around a second coupling shaft for coupling the upper housing and the coupling portion.

Thus, in the portable terminal described in Patent Literature 1, there arises a problem that, at the time where a user supports the lower housing by using both hands and operates the operation portion by using both hands in the laterally opened state, the fingers of the left hand are interfered with the coupling portion and hence the operability is bad.

This invention is made in order to remove the aforesaid inconvenience and an object of this invention is to provide, a portable electronic device which can open a first housing and a second housing longitudinally and laterally, and can obtain good operability in a laterally opened state.

### Solution to Problem

A portable electronic device according to the invention is configured by including: a first housing which is provided with an operation portion; a second housing which is provided with a display portion; a coupling portion which couples the first housing and the second housing; a first coupling shaft which, so as to couple the first housing and the coupling portion, is disposed between an operation surface provided with the operation portion and a surface on an opposite side of the operation surface, along a second direction orthogonal to a first direction along which the first housing and the coupling portion are arranged and in parallel to the operation surface; and a second coupling shaft which, so as to couple the second housing and the coupling portion, is disposed to be directed to a direction different from the direction of the first coupling shaft and is disposed at a position deviated along the second direction from a center of a length along the second direction in the first housing, wherein in a closed state where the first housing and the second housing are relatively stacked, a surface of the coupling portion continues to the operation surface of the first housing and the surface of the coupling portion opposes to a display surface of the second housing at which the display portion is provided, in a longitudinally opened state where the first housing and the second housing rotate relatively around the first coupling shaft from the closed state, the coupling portion rotates and the surface of the coupling portion and the operation surface are directed to different directions from each other in a state where the surface of the coupling portion opposes to the display surface of the second housing, and in a laterally opened state where the first housing and the second housing rotate relatively around the second coupling shaft from the closed state, the surface of the coupling portion continues to the operation surface of the first housing and the surface of the coupling portion and the display surface of the second housing are directed to different directions from each other.

As a mode where the surface of the first member continues to the operation surface of the first housing, there is a mode, for example, where the surface of the first member and the operation surface of the first housing are disposed so as to be along the same flat surface or the same curved surface in the laterally opened state. However, the invention also includes a mode that there is a step or a gap of such a degree of not causing a trouble in the operation of the operation portion by the fingers of a user between the surface of the first member and the operation surface of the first housing.

According to the invention, since the first coupling shaft is disposed between the operation surface provided with the operation portion of the first housing and the surface on the opposite side of the operation surface, the contour shape of the coupling portion can be formed not to protrude with respect to the operation surface of the first housing.

That is, in this invention, since the coupling portion does not protrude with respect to the operation surface of the first housing, there is little possibility that the fingers of the user interferes with the coupling portion in the laterally opened state. Thus, the operability of the user in the laterally opened state can be improved as compared with the background art.

Further, in this invention, since the coupling portion does not protrude with respect to the operation surface of the first housing, the effective area of the operation portion with respect to the flat area of the first housing can be secured to be large. Accordingly, it becomes possible to enlarge the sizes of the operation buttons and the arrangement interval thereof and hence the degree of freedom of the design is improved.

Further, in this invention, since the surface of the first member of the coupling portion for accommodating the first coupling shaft continues to the operation surface of the first housing in the laterally opened state, the operability of the operation portion for seeing moving pictures and playing games etc. in the laterally opened state can be further improved.

The portable electronic device according to the invention is configured so that the coupling portion includes a first member into which the first coupling shaft is inserted and a second member into which the second coupling shaft is inserted, and at least one of the first housing supporting portion and the first member is provided in plural so as to be disposed with a predetermined distance therebetween along the second direction of the first housing and to sandwich the other of the first housing supporting portion and the first member.

In this invention, at least one of the first housing supporting portion, which is provided at the first housing and into which the first coupling shaft is inserted, and the first portion, which is provided at the coupling portion and into which the first coupling shaft is inserted, is provided in plural, and the other of first housing supporting portion and the first portion is sandwiched by the plural ones. Thus, since the both end portions of the first coupling shaft can be supported, the intensity necessary for the first coupling shaft can be set to be low as compared with the case where only one of the both ends of the first coupling shaft is supported.

In other words, according to the invention, since the diameter of the first coupling shaft can be made small, the coupling portion can be made thin and miniaturized. In this state, the coupling portion can also be formed so as not to protrude with respect to the operation surface of the first housing.

The portable electronic device according to the invention is configured so that the second member protrudes from the surface of the first member.

According to the invention, since the second coupling shaft is supported by the second member which protrudes from the surface of the first member of the coupling portion, the first coupling shaft and the second coupling shaft are respectively disposed at different levels, whereby the flat area of the first housing can be secured to be large.

The portable electronic device according to the invention is configured so that the second member has a slanted surface extending from the surface of the first member to a top portion with respect to the surface of the first member.

According to the invention, since the second member has the slanted surface continuing from the surface of the first member, the degree of the interference of the second member with respect to the fingers of a user can be made small in the laterally opened state, the operability can be improved.

The portable electronic device according to the invention is configured so that the slanted surface is an arcuate surface of a concave shape.

According to the invention, since the degree of the interference of the second member with respect to the fingers of a user can be made minimum in the laterally opened state, the operability can be further improved.

The portable electronic device according to the invention is configured by including: a concave portion which is provided at the slanted surface; and a convex portion which is provided at the second housing and capable of being inserted into the concave portion, wherein in each of the closed state where the first housing and the second housing are relatively stacked and the longitudinally opened state where the first housing and the second housing rotate relatively around the first coupling shaft, the convex portion is inserted into the concave portion, and in the laterally opened state where the first housing and the second housing rotate relatively around the second coupling shaft, the convex portion is extracted from the concave portion.

According to the invention, since the convex portion provided at the second housing is inserted into the concave portion provided at the slanted surface of the second member constituting the coupling portion in each of the closed state and the longitudinally opened state, the relative position between the second housing and the coupling portion can be surely maintained in cooperation with the second rotation shaft in each of the closed state and the longitudinally opened state.

In other words, in this invention, since a load applied to the second rotation shaft can be reduced in each of the closed state and the longitudinally opened state, it becomes possible to reduce a possibility that each of the second rotation shaft, the coupling portion for supporting the second rotation shaft and the inner structure of the second housing is broken.

Further, according to the invention, since the intensity required for each of the second rotation shaft, the coupling portion for supporting the second rotation shaft and the second housing is low, the diameter of the second rotation shaft can be made small and the thickness of each of the coupling portion and the second housing can be made small, whereby the entire configuration of the portable electronic device can be made small.

The portable electronic device according to the invention is configured so that the first housing supporting portion is provided in plural, and the first member is sandwiched between the first housing supporting portions.

In this invention, since the first member is sandwiched between a plurality of the first housing supporting portions, the end faces of the first housing supporting portions can be set to be the same plane with respect to the side end surface of the first housing.

Thus, in this invention, in the case of disposing the operation button of an one-push opener at the end portion of the first coupling shaft, for example, in order to shift to the longitudinally opened sate where the first housing and the second housing rotate relatively around the first coupling shaft from the closed state where the first housing and the second housing are relatively stacked, even when the user pushes the operation button of the one-push opener by using the finger of the one hand of the user holding the first housing in the state that the first housing is held by the one hand, the circumferential portion of the operation button, that is, the end face of the first housing supporting portion does follow the second housing relatively rotating with respect to the first housing.

Thus, in this invention, good operability of the operation button can be obtained even in the case where the operation button of the one-push opener is disposed at the end portion of the first coupling shaft.

The portable electronic device according to the invention is configured so that a holding unit for holding a relative position between the first housing and the second housing is accommodated within the second member.

According to the invention, since the holding units for holding the closed state are accommodated within the second member, the thickness of the first housing or the second housing can be made small.

The portable electronic device according to the invention is configured by including: a first engagement portion which is provided on a side of the operation surface of the first housing at which the operation portion is provided in opposite to a side thereof coupled to the coupling portion; and a second engagement portion which is provided at a position opposing to the first engagement portion on the display surface provided at the display portion of the second housing and is capable of engaging with the first engagement portion, wherein one of the first engagement portion and the second engagement portion is an opening portion, and the other of the first engagement portion and the second engagement portion is an engagement click which is inserted into and capable of being engaged with the opening portion, in each of the closed state where the first housing and the second housing are relatively stacked and the longitudinally opened state where the first housing and the second housing rotate relatively around the first coupling shaft, the opening portion and the engagement click are not engaged with each other, and in the laterally opened state where the first housing and the second housing rotate relatively around the second coupling shaft, the engagement click is engaged with the opening portion.

In this invention, since the first engagement portion provided at the operation surface of the first housing does not mutually engage with the second engagement portion provided at the display surface of the second housing in the closed state, there arises no obstacle at the time of opening around the first coupling shaft so as to shift to the longitudinally opened state from the closed state.

Further, in this invention, at the time of shifting to the laterally opened state from the closed state around the second coupling shaft, when the second housing is started to rotate around the second coupling shaft with respect to the first housing, the first engagement portion engages with the second engagement portion. Thus, a sufficient intensity can be obtained and the laterally opened state can be attained stably.

The portable electronic device according to the invention is configured so that an antenna is provided at an end portion in the first direction on the second housing.

In this invention, since the antenna is provided at the end portion in the longitudinal direction on the second coupling shaft side of the second housing, the area of the operation portion can be secured to be large. Further, good receiving sensitivity and transmission efficiency can be obtained in the laterally opened state and hence the communication property can be improved.

A portable electronic device according to the invention is configured by including: a first housing which is provided with an operation portion; a second housing which is provided with a display portion; a coupling portion which couples the first housing and the second housing so as to be rotatable; a first coupling shaft which is capable of rotating the first housing and the second housing in a longitudinal direction; and a second coupling shaft which is capable of rotating the first housing and the second housing in the second direction orthogonal to the first direction, wherein in a closed state where the first housing and the second housing are stacked, the first coupling shaft locates on a lower side in a thickness direction of the first housing than the second coupling shaft, the coupling portion includes a first member into which the first coupling shaft is inserted and a second member into which the second coupling shaft is inserted, and the second member protrudes from the surface of the first member and has a slanted surface extending from the surface of the first member to a top portion of the second member.

In this invention, since the second member has the slanted surface continuing to the top portion, the second member scarcely interferes with the fingers of a user operating the operation portion in the laterally opened state.

A portable electronic device according to the invention is configured by including: a first housing which is provided with an operation portion; a second housing which is provided with a display portion; a coupling portion which couples the first housing and the second housing so as to be rotatable; a first coupling shaft which is capable of rotating the first housing and the second housing in a longitudinal direction; and a second coupling shaft which is capable of rotating the first housing and the second housing in the second direction orthogonal to the first direction, wherein in a closed state where the first housing and the second housing are stacked, the first coupling shaft locates on a lower side in a thickness direction of the first housing than the second coupling shaft, the coupling portion includes a first member into which the first coupling shaft is inserted and a second member into which the second coupling shaft is inserted, and the second member locates only on the second housing side than a center in a lateral direction of the first housing.

In this invention, since the second member locates only on the second housing side than the center in the lateral direction of the first housing, the second member scarcely interferes with the fingers of a user operating the operation portion in the laterally opened state.

### Advantageous Effects of the Invention

According to this invention, the portable electronic device can be provided in which there is little possibility that the fingers of a user interferes with the coupling portion in the laterally opened state and hence the operability of the user in the laterally opened state can be improved as compared with the background art.

### BRIEF DESCRIPTION OF THE DRAWINGS

FIG. 1 is a perspective view showing the laterally opened state of a portable electronic device according to a first embodiment of the invention.

FIG. 2 is a perspective view showing the longitudinally opened state of the portable electronic device according to the first embodiment of the invention.

FIG. 3 is a perspective view showing the closed state of the portable electronic device according to the first embodiment of the invention.

FIG. 4 is an exploded perspective view of a coupling portion.

FIG. 5 is a sectional diagram at a position V-V in FIG. 4.

FIG. 6 is a sectional diagram at a position VI-VI in FIG. 4.

FIG. 7 is an exploded perspective view showing a first engagement portion and a second engagement portion.

FIG. 8 is a perspective view showing the laterally opened state of a portable electronic device according to a second embodiment of the invention.

FIG. 9 is a perspective view showing the longitudinally opened state of the portable electronic device according to the second embodiment of the invention.

FIG. 10 is a perspective view showing the closed state of the portable electronic device according to the second embodiment of the invention.

### DESCRIPTION OF THE EMBODIMENTS

### First Embodiment

Hereinafter, the explanation will be made with reference to the drawings as to a portable electronic device according to an embodiment of the invention.

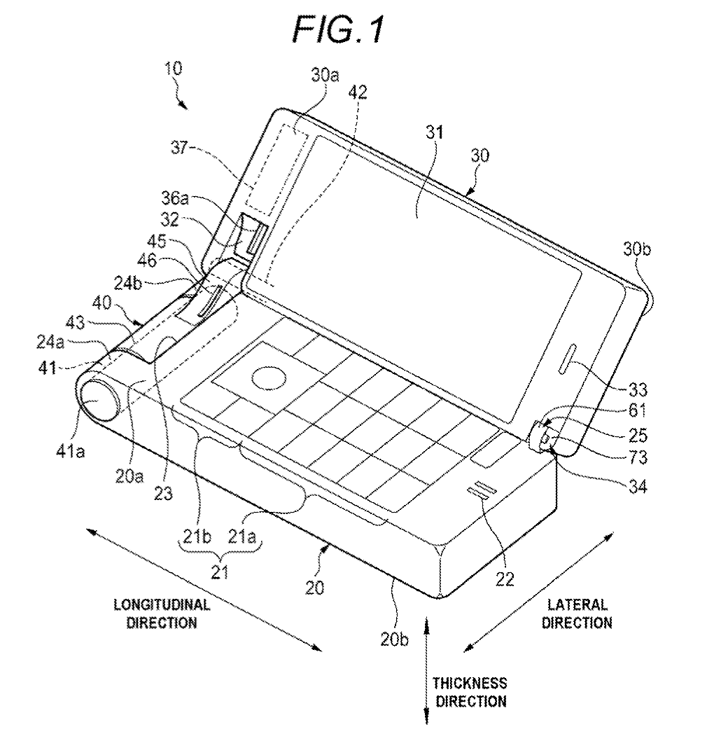

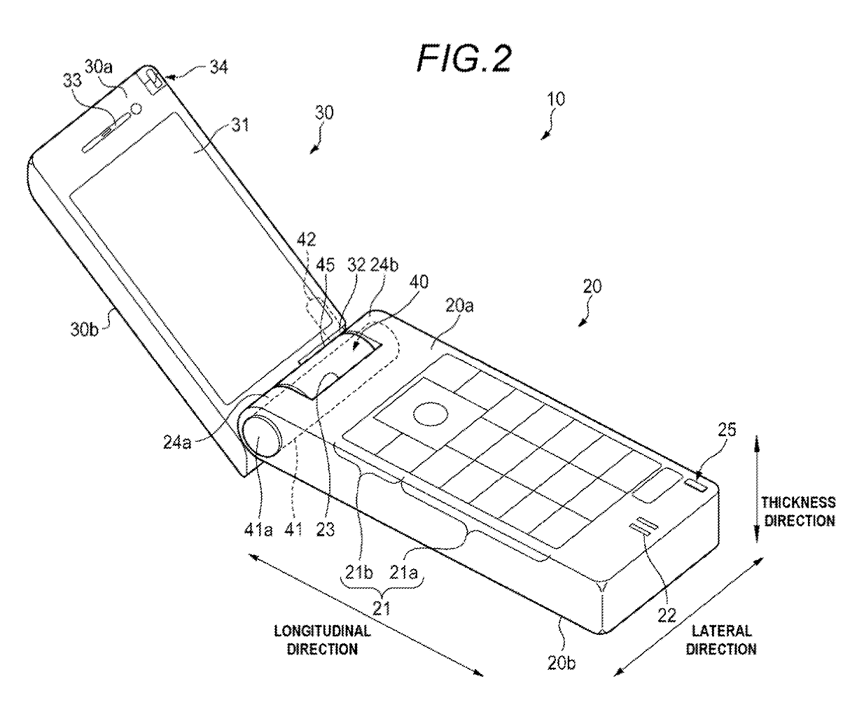

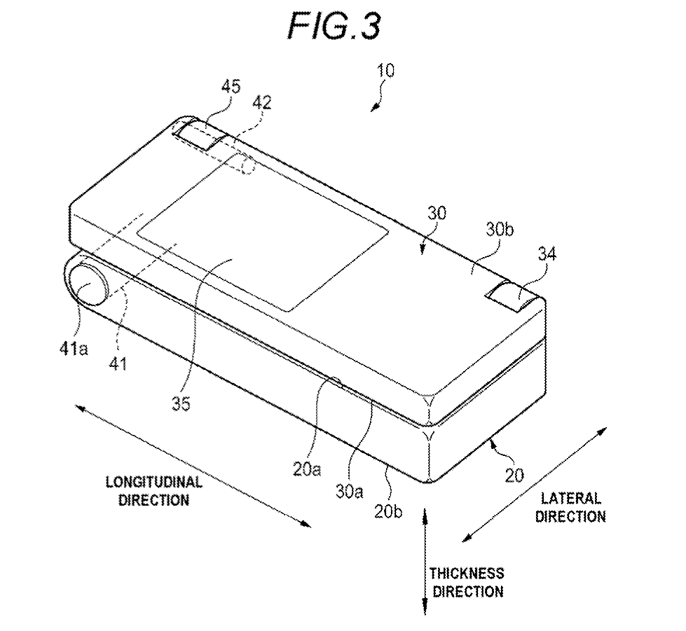

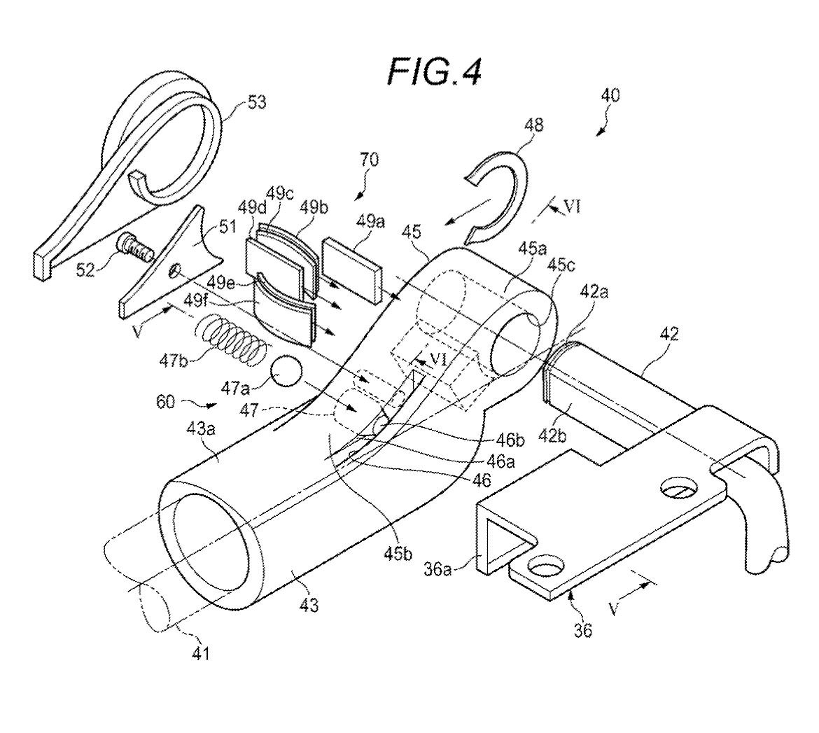

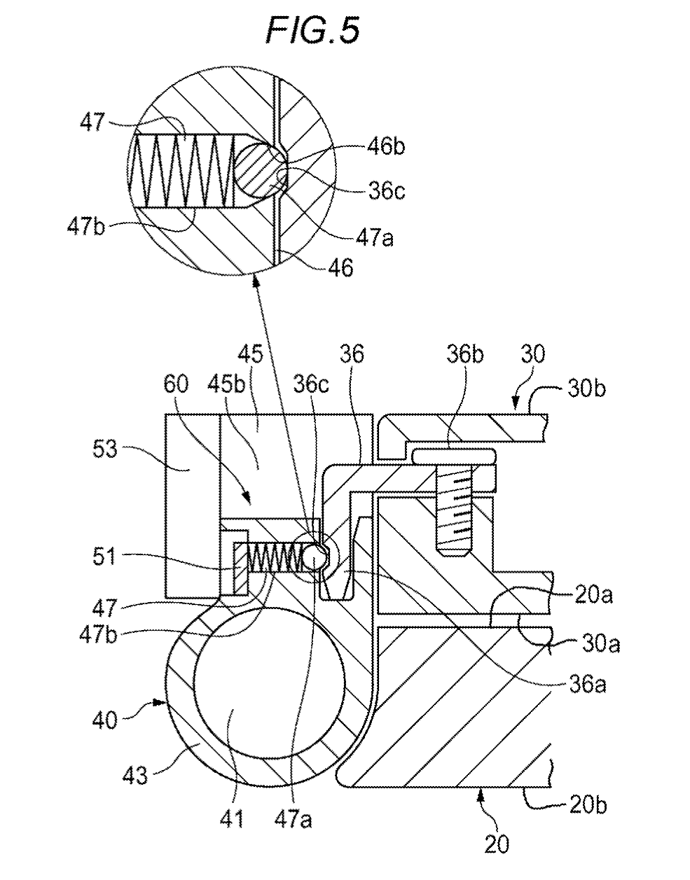

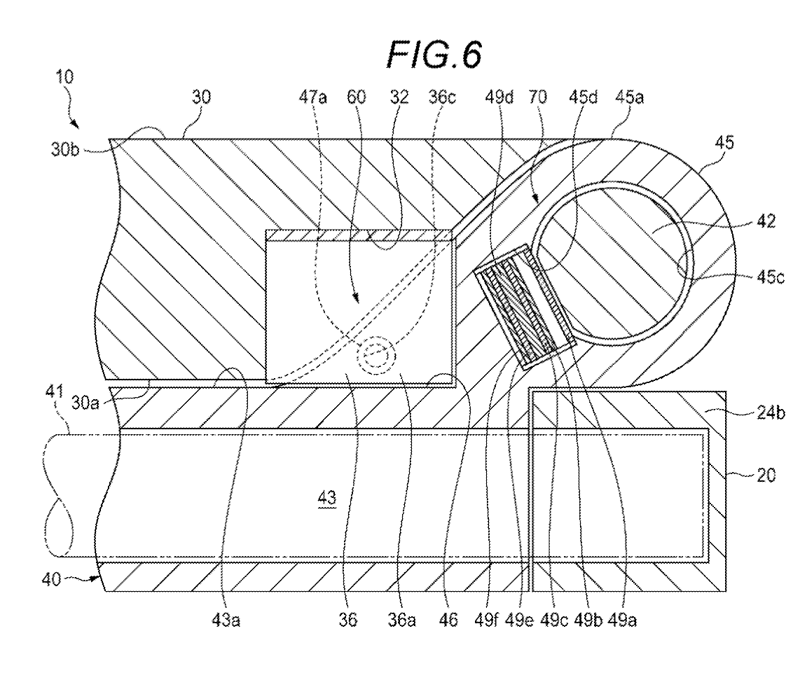

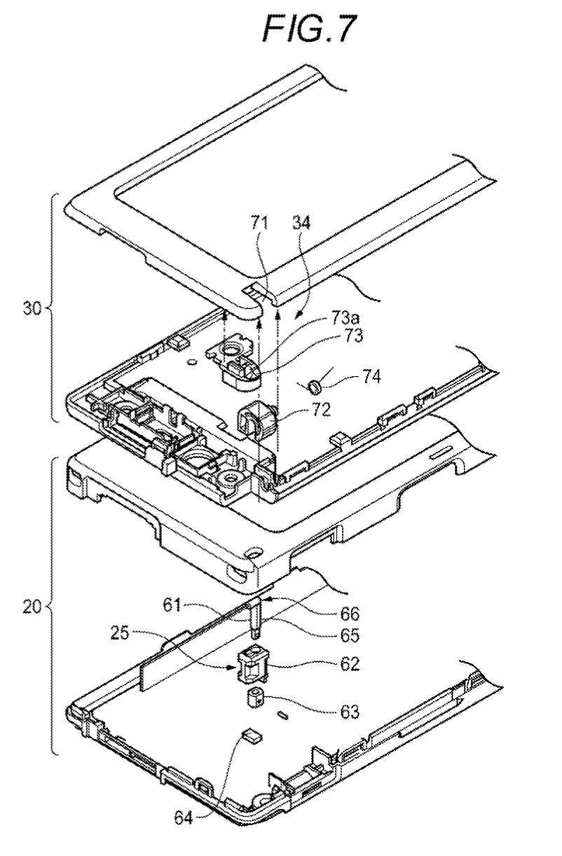

FIG. 1 is a perspective view showing the laterally opened state of the portable electronic device according to the first embodiment of the invention, FIG. 2 is a perspective view showing the longitudinally opened state of the portable electronic device, FIG. 3 is a perspective view showing the closed state of the portable electronic device, FIG. 4 is an exploded perspective view of a coupling portion, FIG. 5 is a sectional diagram at a position V-V in FIG. 4, FIG. 6 is a sectional diagram at a position VI-VI in FIG. 4, and FIG. 7 is an exploded perspective view showing a first engagement portion and a second engagement portion.

FIGS. 1 to 3 show the first embodiment of the invention. A portable terminal 10 as the portable electronic device according to the first embodiment includes a first housing 20 of a rectangular box shape, a second housing 30 of a rectangular box shape and a coupling portion 40 for coupling the first housing 20 and the second housing 30.

In the portable terminal 10, the first housing 20 and the coupling portion 40 are coupled via a first coupling shaft 41 and the second housing 30 and the coupling portion 40 are coupled via a second coupling shaft 42.

In the first embodiment described below, a first direction of the first housing 20 along which the first housing 20 and the coupling portion 40 are arranged is called as a longitudinal direction, a second direction of the first housing 20 orthogonal to the first direction is called as a lateral direction, and a direction orthogonal to both the longitudinal direction and the lateral direction is called as a thickness direction.

In the second housing 30, a longitudinal direction, a lateral direction and a thickness direction are also respectively called in the similar manner as the longitudinal direction, the lateral direction and the thickness direction of the first housing 20.

The portable terminal 10 takes a closed state (a state shown in FIG. 3) where the first housing 20 and the second housing 30 are relatively stacked, a longitudinally opened state (a state shown in FIG. 2) where the second housing 30 and the coupling portion 40 are integrally rotated with respect to the first housing 20 around the first coupling shaft 41 from the closed state, and a laterally opened state (a state shown in FIG. 1) where the second housing 30 rotates with respect to the first housing 20 around the second coupling shaft 42 from the closed state.

In the first housing 20, an operation surface 20a is provided with an operation portion 21 which corresponds to a portion to be held by a single hand or both hands when a user uses the portable terminal 10 and has an input key group 21a for inputting numerals and characters and a function key group 21b for performing various kinds of settings and switching functions.

The first housing 20 is provided with a pair of first housing supporting portions 24a, 24b at the one end portion (end portion on the function key group 21b side) along the longitudinal direction and also provided with a microphone 22 on the operation surface 20a at the other end portion along the longitudinal direction.

The microphone 22 is provided in order to collect voice of a user when the portable terminal 10 is placed in the longitudinally opened state so as to use the portable terminal 10 as a telephone.

The first housing supporting portions 24a, 24b are protruded in the longitudinal direction from the lateral end surface of the first housing 20 so that the end surface of an almost U-shape continues to the side end surface of the first housing 20 and are disposed with a predetermined distance therebetween via a notch 23 along the lateral direction of the first housing 20.

Each of these first housing supporting portions 24a, 24b does not protrude toward the operation surface 20a of the first housing 20 nor toward an outer surface 20b on the opposite side of the operation surface 20a.

An operation button 41a of an one-push opener, which is a mechanism for shifting the portable terminal 10 to the longitudinally opened state from the closed state, is disposed on the end surface of the first housing supporting portion 24a.

The one-push opener is the mechanism for shifting the portable terminal 10 to the longitudinally opened state from the closed state by releasing a built-in spring (not shown) hanged over between the first housing 20 and the coupling portion 40 to an expanded state from a compressed state.

In the first housing 20, the both end portions of the first coupling shaft 41 are supported by the first housing supporting portions 24a, 24b, respectively. In other words, the first coupling shaft 41 is disposed, between the operation surface 20a and the outer surface 20b on the opposite side of the operation surface 20a, along the lateral direction (second direction) orthogonal to the longitudinal direction (first direction) along which the first housing 20 and the coupling portion 40 are arranged and in parallel to the operation surface 20a.

Thus, since the first housing 20 is not required to provide a projection for housing the first coupling shaft 41 on the operation surface 20a, the operation surface 20a can be made flat.

The second housing 30 is provided with a main display portion 31 such as an LCD on a display surface 30a which opposes to the operation surface 20a of the first housing 20 in the closed state (state in FIG. 3) and also provided with a sub-display portion 35 on an outer surface 30b on the opposite side of the surface 30a.

The main display portion 31 is used as a display screen for games and television broadcasting in the longitudinally opened state and the laterally opened state.

The second housing 30 is provided, at the one end portion along the longitudinal direction of the display surface 30a, with a sound portion 33 for outputting transmitted voice etc. by being abutted against the ear of the user at the tine of using the terminal as a telephone in the longitudinally opened state, and also provided with a recess 32 and an antenna 37 (see FIG. 1) at the other end portion (coupling portion 40 side) along the longitudinal direction thereof.

The antenna 36 is disposed within the second housing 30.

As also shown in FIG. 4, the coupling portion 40 includes a first member 43 of an almost cylindrical shape into which the first coupling shaft 41 is passed and further includes a second member 45 provided at the outer side of the first member.

The first member 43 is configured in an almost cylindrical shape in a manner that the first member partially has a surface 43a which forms a continuous surface not causing any step, etc. with respect to the operation surface 20a of the first housing 20 in the longitudinally opened state and the laterally opened state.

The first member 43 can be accommodated within the notch 23 between the first housing supporting portions 24a, 24b of the first housing 20 and can be rotatable with respect to the first housing 20 around the first coupling shaft 41 by inserting the first coupling shaft 41 therein.

The first member 43 has a shape and a diameter size not protruding with respect to the operation surface 20a of the first housing 20 in the longitudinally opened state or the laterally opened state of the portable terminal 10.

The surface 43a may have a flat surface, an arcuate surface or a curved surface etc., for example, in corresponding to the surface shape of the operation surface 20a, and a display portion and operation buttons etc. may be separately disposed on the surface 43a.

The second member 45 is shaped to have an end surface of an almost water-drop shape in a manner that the second member protrudes along a generating line of the first member 43 from the surface 43a to a predetermined position away from the one end surface of the first member 43 and also protrudes along the radial direction of the first member 43 to thereby continuously form a slanted surface 45b to the top portion 45a of the second member 45 from the surface 43a of the first member 43.

That is, the second member 45 locates only on the second housing 30 side deviated along the lateral direction from the center of the length along the lateral direction of the first housing 20. The slanted surface 45b is configured to have an arcuate surface of a concaved shape.

The second member 45 is accommodated within a recess 32 of the second housing 30 and pivotally supported by the second coupling shaft 42 along the longitudinal direction of the second housing 30.

Thus, in the coupling potion 40, the first coupling shaft 41 and the second coupling shaft 42 are disposed in a so-called double level fashion in a manner that the first coupling shaft 41 and the second coupling shaft 42 are disposed along different planes and directed to in different directions from each other.

In other words, in the closed state, the first coupling shaft 41 locates on the lower side than the second coupling shaft 42 in the thickness direction of the first housing 20 and the second housing 30.

Further, the coupling portion 40 is made rotatable with respect to the first housing 20 around the first coupling shaft 41 and also rotatable with respect to the second housing 30 around the second coupling shaft 42.

The coupling portion 40 configured in this manner is provided with a concave portion 46 at the slanted surface 45b of the second member 45.

The concave portion 46 is configured as a slit formed toward the axis line of the first member 43. A convex portion 36a fixed to the second housing 30 and exposed from the recess 32 can be inserted into the concave portion (see FIG. 1).

As also shown in FIG. 5, the convex portion 36a is configured as a part of an engagement member 36 formed by a sheet metal. This convex portion 36a has an almost plate shape capable of being inserted into the concave portion 46 and is provided at one major surface thereof with an engagement concave portion 36c. The engagement member 36 is coupled to the second coupling shaft 42 and fixed to the inner portion of the second housing 30 by means of a screw 36b.

Thus, in the portable terminal 10, since the convex portion 36a is inserted into the concave portion 46 in the closed state and the longitudinally opened state, the coupling intensity between the coupling portion 20 and the second housing 30 in the closed state and the longitudinally opened state can be secured and a load applied to the second coupling shaft 42 can be reduced.

As also shown in FIG. 5, the coupling portion 40 is configured in a manner that a first holding unit 60 is accommodated within the second member. The first holding unit 60 includes a round hole 46b provided at the one inner side surface 46a, a space 47 of a cylindrical shape which continues to the round hole 46b and is provided within the second member 45, and a spherical member 47a and a spring 47b each accommodated within the space 47.

The space 47 has an inner diameter size larger than the inner diameter size of the round hole 46b. The diameter size of the spherical member 47a is larger than the inner diameter size of the round hole 46b and smaller than the inner diameter size of the space 47.

Thus, the spherical member 47a partially protrudes from the inner side surface 46a elastically due to the elastic force of the spring 47b without being dropped into the concave portion 46 from the round hole 46b.

Therefore, in the portable terminal 10, when the user shifts the terminal to the closed state from the laterally opened state, the convex portion 36a of the click member 36 is inserted into the concave portion 46 while pushing the spherical member 47a into the round hole 46b by compressing the spring 47b. Then, when the engagement concave portion 36c of the convex portion 36a reaches the spherical member 47a, the spherical member 47a is fit into the engagement concave portion 36c by the spring 47b.

Thus, in the portable terminal 10, when the user shifts the terminal to the closed state from the laterally opened state, the first holding unit 60 notifies to the user that the shift to the closed state from the laterally opened state is completed by a click generated when the spherical member 47a fits into the engagement concave portion 36c. Further, the first holding unit 60 holds the relative position of the first housing 20 and the second housing 30 so as not to shift to the laterally opened state from the closed state so long as a force of a constant value or more is not applied thereto.

Returning to FIG. 4, the second member 45 is provided with a bearing hole 45c having a circular section for rotatably and pivotally bearing the second coupling shaft 42.

The second coupling shaft 42 is provided at the tip end thereof with a groove 42a continuing in the circumferential direction. The tip end portion protrudes from the bearing hole 45c so that the groove 42a is exposed. The second coupling shaft 42 is inserted into the bearing hole 45c without being dropped from the second member 45 by a C ring 48 attached to the groove 42a.

As shown in FIGS. 4 and 6, the second member 45 is provided with a spring-accommodation space 45d of an almost rectangular parallelepiped shape which partially continues to the inner peripheral surface of the bearing hole 45c. The spring-accommodation space 45d is opened at a side of the second member 45 in opposite to the second housing 30 side.

Within the spring-accommodation space 45d, an outer plate 49a of a flat plate shape as a part of a second holding unit 70, a first leaf spring 49b, a second leaf spring 49c, an intermediate plate 49d of a flat plate shape, a third leaf spring 49e and a fourth leaf spring 49f are accommodated in a stacked state, sequentially from the bearing hole 45c side.

The outer plate 49a is a flat plate with a high rigidity and has a lengthwise and crosswise size larger than the lengthwise and crosswise size of a communication opening of a rectangular shape for communicating between the spring-accommodation space 45d and the baring hole 45c.

Each of the first leaf spring 49b and the second leaf spring 49c is a spring member of an arcuate shape expanded toward the outer plate 49a side. The first and second leaf springs 49b, 49c are stacked in a state that the outer side surface of the first leaf spring 49b is pushed against the outer plate 49a.

The intermediate plate 49d is a flat plate having a high rigidity.

Each of the third leaf spring 49e and the fourth leaf spring 49f is a spring member of an arcuate shape expanded toward a side in opposite to the intermediate plate 49d side. The third and fourth leaf springs 49e, 49f are stacked in a state that the outer side surface of the fourth leaf spring 49f is pushed against the inner surface of the spring-accommodation space 45d.

Since the intermediate plate 49d is disposed between the second leaf spring 49c and the third leaf spring 49e, even if the second and third leaf springs relatively deviate in position along the surface direction of the intermediate plate 49d, an elastic force of a constant value or more can be surely transmitted to the outer plate 49a.

The first leaf spring 49b, the second leaf spring 49c, the third leaf spring 49e and the fourth leaf spring 49f always apply a constant elastic force toward the axis line from the outside of the second coupling shaft 42 by the outer plate 49a.

The outer plate 49a is made in a generating-line contact with the outer peripheral surface of the second coupling shaft 42 in the laterally opened state and made in a surface contact with the flat portion 42b of the second coupling shaft 42 in the closed state and the longitudinally opened state.

Thus, in the portable terminal 10, when the user shifts the terminal to the closed state from the laterally opened state, according to the function of the second holding unit 70, a force necessary for rotating the second housing 30 with respect to the first housing 20 around the second coupling shaft 42 changes when the outer plate 49a is made in the surface contact with the flat portion 42b of the second coupling shaft 42. Thus, the user is notified by the feeling that the shift to the closed state from the laterally opened state is completed. Further, the second holding unit 70 holds the relative position between the first housing 20 and the second housing 30 so as not to shift to the laterally opened state from the closed state so long as a force of a constant value or more is not applied thereto.

In the second member 45 configured in this manner, each of the opening of the spring-accommodation space 45d and the opening of the aforesaid space 47 is covered by a lid member 51.

The lid member 51 is attached to the side surface of the second member 45 by means of a screw 52 and is covered by a cover member 53 together with the end portion of the second coupling shaft 42.

As shown in FIG. 7, a first engagement portion 25 provided at the first housing 20 includes an engagement click 61, a holding portion 62 for holding the engagement click 61, a stopper 63 for preventing the engagement click 61 from dropping from the holding portion 62, and a first housing magnet 64.

The engagement click 61 has a first protruding portion 65 protruding to the second housing 30 from the first housing 20 and a second protruding portion 66 which is coupled to the first protruding portion 65 and extends in a direction crossing with the first protruding portion.

A second engagement portion 34 provided at the second housing 30 includes an opening 71, a first accommodation portion 72 which is disposed rotatably within the opening 71 and accommodates the first protruding portion 65 and in which a magnet is provided by the insert molding, a second accommodation portion 73 which rotates integrally with the second housing 30 and has an opening portion 73a for accommodating the second protruding portion 66, and a return spring 74 which rotates the second accommodation portion 73 to thereby align the direction of the opening of the first accommodation portion 72 with the direction of the second accommodation portion 73.

Accordingly, in the portable terminal 10, the engagement click 61 protrudes toward the direction of the second engagement portion 34 in the closed state by the magnetic force of the magnet provided within the first accommodation portion 72 by the insert molding. In this state, the first engagement portion 25 does not engage with the second engagement portion 34.

When the second housing 30 is rotated around the second coupling shaft 42 from this state so as to be laterally opened, the second accommodation portion 73 rotates integrally with the second housing 30, whereby the opening portion 73a engages with and locks the second protruding portion 66 of the engagement click 61. That is, the first engagement portion 25 engages with the second engagement portion 34.

As a result, since the first engagement portion 25 of the first housing 20 does not mutually engage with the second engagement portion 34 of the second housing 30 in the closed state, there arises no obstacle at the time of opening around the first coupling shaft 41 so as to shift to the longitudinally opened state from the closed state.

Further, at the time of opening around the second coupling shaft 42 so as to shift to the laterally opened state from the closed state, the first engagement portion 25 engages with the second engagement portion 34 when the second housing 30 starts to rotate around the second coupling shaft 42. Thus, a sufficient intensity can be obtained and the lateral opening operation can be performed stably.

The portable terminal 10 according to the first embodiment is configured in the manner that, in the closed state, the surface 43a of the coupling portion 40 continues to the operation surface 20a of the first housing 20 and the surface 43a of the coupling portion 40 opposes to the display surface 30a of the second housing 30; in the longitudinally opened state, the coupling portion 40 rotates in the state that the surface 43a of the coupling portion 40 opposes to the display surface 30a of the second housing 30 and the surface 43a of the coupling portion 40 and the operation surface 20a of the first housing 20 are directed to different directions from each other; and in the laterally opened state, the surface 43a of the coupling portion 40 continues to the operation surface 20a of the first housing 20 and the surface 43a of the coupling portion 40 and the display surface 30a of the second housing 30 are directed to different directions from each other,

According to the portable terminal 10 of the first embodiment described above, since the first coupling shaft 41 is disposed between the operation surface 20a at which the operation portion 21 of the first housing 20 is provided and the outer surface 20b on the opposite side of the operation surface 20a, the coupling portion 40 can be formed so as not to protrude from the operation surface 20a of the first housing 20.

That is, according to the portable terminal 10, since the coupling portion 40 does not protrude with respect to the operation surface 20a of the first housing 20, there is little possibility that the fingers of the user interferes with the coupling portion 40 in the laterally opened state. Thus, the operability of the user who operates the operation portion 21 for seeing moving pictures and playing games etc. in the laterally opened state can be improved as compared with the background art.

Further, according to the portable terminal 10, since the coupling portion 40 does not protrude with respect to the operation surface 20a of the first housing 20, the effective area of the operation portion 21 with respect to the flat area of the first housing 20 can be secured to be large. Accordingly, it becomes possible to enlarge the sizes of the operation buttons 21a and the arrangement interval thereof and hence the degree of freedom of the design is improved.

Furthermore, according to the portable terminal 10, since the pair of first housing supporting portions 24a, 24b provided at the first housing 20 are configured to sandwich the first member 43 constituting the coupling portion 40, the both end portions of the first coupling shaft 41 can be supported. Thus, the intensity necessary for the first coupling shaft 41 can be set to be low as compared with the case where only one of the both ends of the first coupling shaft 41 is supported.

In other words, according to the portable terminal 10, since the diameter of the first coupling shaft 41 can be made small, the coupling portion 40 can be made thin and miniaturized. In this state, the coupling portion 40 can also be formed so as not to protrude with respect to the operation surface 20a of the first housing 20.

Furthermore, according to the portable terminal 10, since the surface 43a of the first member 43 constituting the coupling portion 40 continues to the operation surface 20a of the first housing 20 in the laterally opened state, the operability of the operation portion 21 for seeing moving pictures and playing games etc. in the laterally opened state can be further improved.

Furthermore, according to the portable terminal 10, since the first coupling shaft 41 and the second coupling shaft 42 are respectively disposed at different levels along different planes by the first member 43 and the second member 45 constituting the coupling portion 40, the flat area of the first housing 20 can be secured to be large.

Furthermore, according to the portable terminal 10, since the second member 45 has the slanted surface 45b which continues from the surface 43a. of the first member 43 to the top with respect to the surface 43a of the first member 43, the degree of the interference of the second member 45 with respect to the fingers of a user can be made small in the laterally opened state and hence the operability of the operation portion 21 can be improved.

Furthermore, according to the portable terminal 10, since the slanted surface 45b of the second member 45 has the arcuate surface of the concaved shape, the degree of the interference of the second member 45 with respect to the fingers of a user can be made minimum in the laterally opened state and hence the operability of the operation portion 21 can be further improved.

Furthermore, according to the portable terminal 10, since the concave portion 46 and the convex portion 36a capable of being inserted into and removed from the concave portion 46 in the closed state, the longitudinally opened state and the laterally opened state are provided, the coupling intensity between the first housing 20 and the second housing 30 in the closed state and the longitudinally opened state and hence a load applied to the second coupling shaft 42 can be reduced.

Furthermore, according to the portable terminal 10, since the first member 43 as a supporting portion of the coupling portion is sandwiched between the pair of the first housing supporting portions 42a and 42b, the end faces of the first housing supporting portions 42a and 42b can be set to be the same plane with respect to the side end face of the first housing 20.

In other words, according to the portable terminal 10, even when the user pushes the operation button 41a of the one-push opener by using the finger of the one hand of the user holding the first housing 20 in the state that the first housing 20 is held by the one hand, the circumferential portion of the operation button 41a, that is, the end face of the first housing supporting portion 42a does not rotate in a manner of following the second housing 30. Thus, good operability of the operation button 41a can be obtained.

Furthermore, according to the portable terminal 10, since the first holding unit 60 and the second holding unit 70 for holding the relative position of the first housing 20 and the second housing 30 in the closed state are accommodated within the second member 45, the thickness of the first housing 20 or the second housing 30 can be made small.

Furthermore, according to the portable terminal 10, since the engagement portion 25 provided at the operation surface 20a of the first housing 20 does not mutually engage with the second engagement portion 34 provided at the display surface 30a of the second housing 30 in the closed state, there arises no obstacle at the time of opening around the first coupling shaft 41 so as to shift to the longitudinally opened state from the closed state.

Furthermore, according to the portable terminal 10, at the time of opening around the second coupling shaft 42 so as to shift to the laterally opened state from the closed state, the first engagement portion 25 engages with the second engagement portion 34. Thus, a sufficient intensity can be obtained and the lateral opening operation can be performed stably.

Furthermore, according to the portable terminal 10, since the antenna 37 is provided at the end portion in the longitudinal direction on the second coupling shaft 42 side of the second housing 30, the area of the operation portion 21 can be secured to be large. Further, good receiving sensitivity and transmission efficiency can be obtained in the laterally opened state and hence the communication property can be improved.

### Second Embodiment

Next, the explanation will be made as to a portable terminal 10B as a portable electronic device according to a second embodiment of the invention.

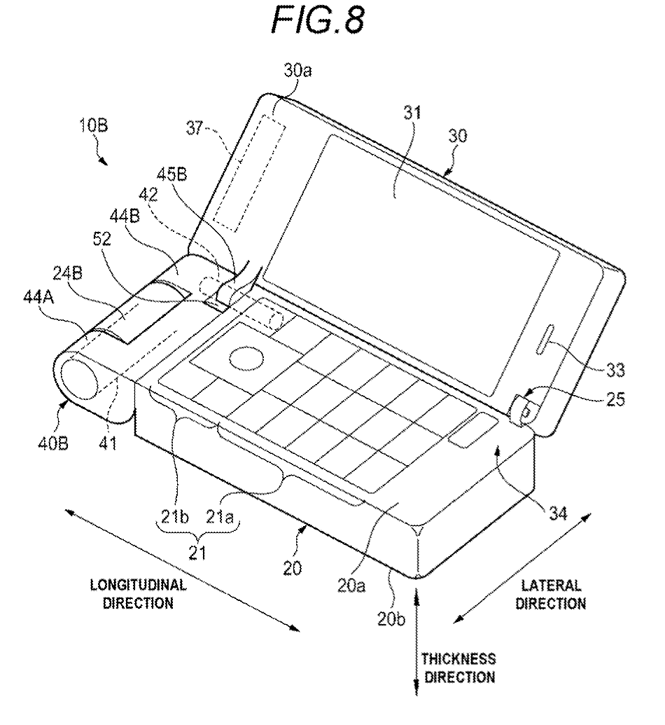

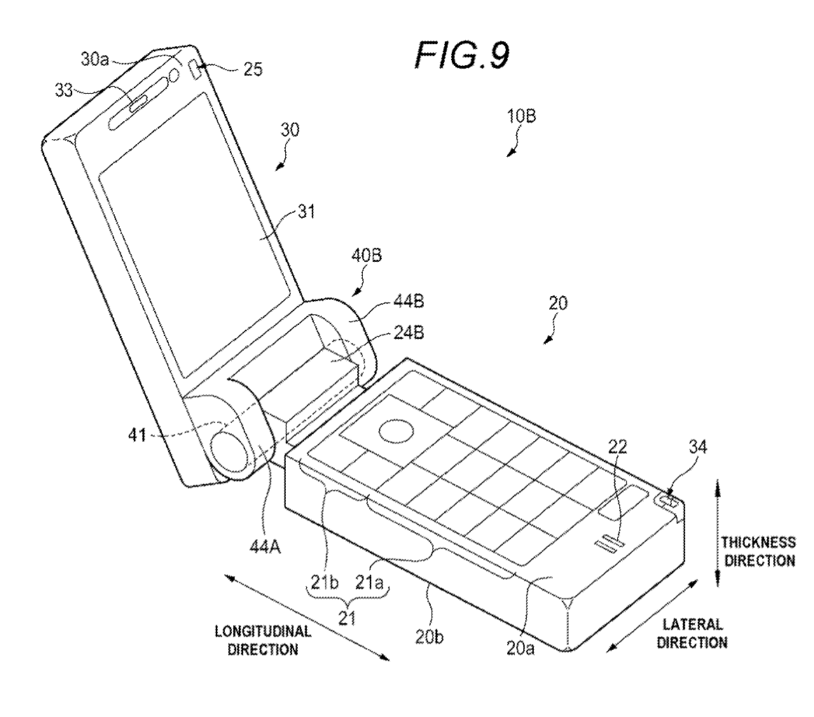

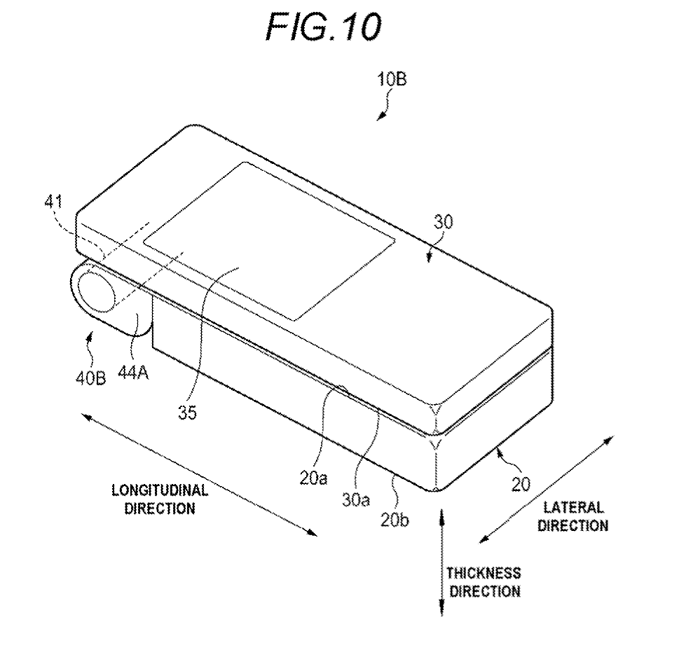

FIG. 8 is a perspective view showing the laterally opened state of the portable terminal according to the second embodiment, FIG. 9 is a perspective view showing the longitudinally opened state of the portable terminal, and FIG. 10 is a perspective view showing the closed state of the portable terminal.

In the second embodiment described below, portions common to those of the portable terminal 10 of the aforesaid first embodiment are referred to by the common symbols, with duplicated explanation thereof being omitted.

As shown in FIGS. 8 to 10, in the portable terminal 10B of the second embodiment, a pair of first members 44A, 44B are provided at a coupling portion 40B, a first housing supporting portion 24B is provided at the first housing 20, and the first housing supporting portion 24B is sandwiched between the pair of first members 44A, 44B.

Further, in the portable terminal 10B, a second member 45B corresponding to the second member 45 provided at the coupling portion 40 in the first embodiment is provided at a second housing 30 and a recess 52 corresponding to the recess 32 provided at the second housing 30 in the first embodiment is provided at the coupling portion 40.

Furthermore, in the portable terminal 10B, the first engagement portion 25 provided at the first housing 20 in the first embodiment is provided at the second housing 30 and the second engagement portion 34 provided at the second housing 30 in the first embodiment is provided at the first housing 20.

According to the portable terminal 10B of the second embodiment explained above, since the first coupling shaft 41 is disposed between the operation surface 20a of the first housing 20 and the outer surface 20b on the opposite side of the operation surface 20a, the action and effects similar to those of the aforesaid first embodiment can be obtained. Further, since the second member 45B is not provided at the coupling portion 40B, the second member 45B can be further miniaturized and the coupling portion 40 can be configured so as not to protrude with respect to the operation surface 20a of the first housing 20.

The portable electronic device according to this invention is not limited to the aforesaid respective embodiments and suitable modifications and improvements etc. may be performed.

For example, although the mode of sandwiching the first member 43 by the pair of first housing supporting portions 24a, 24b is explained as an example in the first embodiment and the mode of sandwiching the first housing supporting portion 24B by the pair of the first members 44A, 44B is explained as an example in the second embodiment, this invention may contain modes of employing a plurality of the first housing supporting portions and a plurality of the first members, respectively.

Further, although the surface 43a of the coupling portion 40 is configured to be continuous to the operation surface 20a of the first housing 20, this invention is not limited thereto, and the surface 43a of the coupling portion 40 and the operation surface 20a of the first housing 20 may be configured to have a shape not to interfere with the operation of the fingers of a user.

For example, the surface 43a of the coupling portion 40 may be configured so as to be located at a position relatively lower than the operation surface 43a of the first housing 40 in the thickness direction of the first housing 20.

Further, so long as there arises no problem in the operation of the operation portion by the fingers of a user, the surface 43a of the coupling portion 40 may be configured so as to be located at a position slightly higher or lower relatively than the operation surface of the first housing 20 in the thickness direction of the first housing 20.

Furthermore, when the second member 45 of the coupling portion 40 is configured so as to locate only on the second housing 30 side than the center in the lateral direction of the first housing 20 in the state where the first housing 20 and the second housing 30 are placed in the laterally opened state, the second member 45 may be configured not to have the slanted surface.

In each of the aforesaid embodiments, although the explanation is made as to the examples where the portable terminal is used as an example of the portable electronic devices, this invention can be generally applied to other portable electronic devices.

This application is based on Japanese Patent Application fled on Sep. 12, 2008 (Japanese Patent Application No. 2008-234784), the content of which is incorporated herein as a reference.

### REFERENCE SIGNS LIST

10 portable terminal (portable electronic device)

20 first housing

20a operation surface

20b outer surface (surface on opposite side of operation surface)

21 operation portion

24 first housing supporting portion

25 first engagement portion

30 second housing

31 main display portion (display portion)

34 second engagement portion

36a convex portion

40 coupling portion

41 first coupling shaft

42 second coupling shaft

43 first member

43a surface

45 second member

45a top portion

45b slanted surface

46 concave portion

61 engagement click

60 first holding unit (holding unit)

70 second holding unit (holding unit)

73a opening portion

1.-12. (canceled)

13. A portable electronic device, comprising:
a first housing which is provided with an operation portion;
a second housing which is provided with a display portion; and
a coupling portion which rotatably couples the first housing and the second housing in a first direction and a second direction orthogonal to the first direction, wherein
the coupling portion includes:
a first member which is capable of rotating the first housing and the second housing in the first direction; and
a second member which is capable of rotating the first housing and the second housing in the second direction, wherein
the first member locates on a lower side in a thickness direction of the first housing than the second member in a closed state where the first housing and the second housing are stacked, and
the second member protrudes from the surface of the first member and has a slanted surface extending from the surface of the first member to a top portion of the second member in an opened state where the first housing and the second housing are opened in the second direction.
